(19) United States
(12) Patent Application Publication
(10) Pub. No.: US 2005/0148162 A1
(43) Pub. Date: Jul. 7, 2005

(54) Method of preventing surface roughening during hydrogen pre-bake of SiGe substrates using chlorine containing gases

(76) Inventors: Huajie Chen, Danbury, CT (US); Dan M. Mocuta, Lagrangeville, NY (US); Richard J. Murphy, Clinton Corners, NY (US); Stephen W. Bedell, Wappingers Falls, NY (US); Devendra K. Sadana, Pleasantville, NY (US)

Correspondence Address: Frederick W. Gibb, III;McGinn & Gibb, PLLC, Suite 304, 2568-A Riva Road, Annapolis, MD, 21401, US

(21) Appl. No.: 10/751,207

(22) Filed: Jan. 2, 2004

(51) Int. Cl. H01L 21/20; H01L 21/36; H01L 21/44

(52) U.S. Cl. 438/503; 438/481; 438/607; 438/479; 438/341

(57) ABSTRACT

The invention forms an epitaxial silicon-containing layer on a silicon germanium, patterned strained silicon, or patterned thin silicon-on-insulator surface and avoids creating a rough surface upon which the epitaxial silicon-containing layer is grown. In order to avoid creating the rough surface, the invention first performs a hydrofluoric acid etching process on the silicon germanium, patterned strained silicon, or patterned thin silicon-on-insulator surface. This etching process removes most of oxide from the surface, and leaves only a sub-monolayer of oxygen (typically 1×10¹³-1×10¹⁵/cm² of oxygen) at the silicon germanium, patterned strained silicon, or patterned thin silicon-on-insulator surface. The invention then performs a hydrogen pre-bake process in a chlorine containing environment which heats the silicon germanium, strained silicon, or thin silicon-on-insulator surface sufficiently to remove the remaining oxygen from the surface. By introducing a small amount of chlorine containing gases, the heating processes avoid changing the roughness of the silicon germanium, patterned strained silicon, or patterned thin silicon-on-insulator surface. Then the process of epitaxially growing the epitaxial silicon-containing layer on the silicon germanium, patterned strained silicon, or patterned silicon-on-insulator surface is performed.

### CROSS REFERENCE RELATED APPLICATIONS

The present application is related to a new U.S. Patent Application, filed concurrently, to Chen et al., entitled “A METHOD OF PREVENTING SURFACE ROUGHENING DURING HYDROGEN PREBAKE OF SIGE SUBSTRATES”, having (IBM) Docket No. FIS920030173, assigned to the present assignee, and incorporated herein by reference.

### BACKGROUND OF THE INVENTION

1. Field of the Invention

The invention generally relates to the growth of epitaxial silicon (Si) or silicon germanium (SiₓGe₁₋ₓ, for simplicity, we use SiGe in the following description) on various semiconductor crystal surfaces and more particularly to an improved pre-bake method that removes oxygen and carbon at the semiconductor crystal surfaces, without roughening the surfaces.

2. Description of the Related Art

The surfaces of Si and SiGe wafers normally become covered with a thin native oxide layer when exposed for more than a few minutes in an oxygen-containing environment. In epitaxial processes, the residual oxide (or oxygen contamination) at the surface of the substrate must be minimized to enable the growth of high-quality epitaxial films. Additionally, if the active region of an electrical device fabricated on the substrate is close to the epitaxial growth interface, residual oxygen at the interface may affect the operation or performance of the device. The invention described below removes of residual oxygen without substantially roughening the surface.

### SUMMARY OF THE INVENTION

The invention forms an epitaxial Si layer on a SiGe surface, and avoids creating a rough surface upon which the epitaxial Si layer is grown. In order to avoid creating the rough surface, the invention first performs an HF etching process on the SiGe surface. This etching process removes most of the oxide from the surface, and leaves only a sub-monolayer of oxygen at the SiGe surface. The invention then performs a hydrogen pre-bake process in a chlorine containing environment which heats the SiGe surface sufficiently to remove the remaining oxygen from the SiGe surface. By introducing chlorine containing gases during the heating, the invention avoids roughening the SiGe surface. Then the process of epitaxially growing the Si layer on the SiGe surface is performed.

While only Si epitaxy on SiGe is described above, this invention is also applicable to SiGe epitaxy on SiGe, Si or SiGe epitaxy on patterned strained Si (such as with shallow trench isolation formed in the wafer), and Si or SiGe epitaxy on patterned thin SOI.

These, and other, aspects and objects of the present invention will be better appreciated and understood when considered in conjunction with the following description and the accompanying drawings. It should be understood, however, that the following description, while indicating preferred embodiments of the present invention and numerous specific details thereof, is given by way of illustration and not of limitation. Many changes and modifications may be made within the scope of the present invention without departing from the spirit thereof, and the invention includes all such modifications.

### BRIEF DESCRIPTION OF THE DRAWINGS

The invention will be better understood from the following detailed description with reference to the drawings, in which:

FIG. 1 is a cross-sectional schematic diagram of a partially completed layered structure;

FIG. 2 is a cross-sectional schematic diagram of a partially completed layered structure;

FIG. 3 is a cross-sectional schematic diagram of a partially completed layered structure;

FIG. 4 is a cross-sectional schematic diagram of a partially completed layered structure;

FIG. 5 is a cross-sectional schematic diagram of a partially completed layered structure;

FIG. 6 is a cross-sectional schematic diagram of a partially completed layered structure; and

FIG. 7 is a flow diagram illustrating the invention.

### DETAILED DESCRIPTION OF PREFERRED EMBODIMENTS OF THE INVENTION

The present invention and the various features and advantageous details thereof are explained more fully with reference to the nonlimiting embodiments that are detailed in the following description. Descriptions of well-known components and processing techniques are omitted so as to not unnecessarily obscure the present invention. The examples used herein are intended merely to facilitate an understanding of ways in which the invention may be practiced and to further enable those of skill in the art to practice the invention. Accordingly, the examples should not be construed as limiting the scope of the invention.

The present invention generally relates to Si epitaxy on SiGe surfaces that are normally coated with a thin oxide after experiencing an ambient environment. In epitaxial processes, it is important to reduce the amount of oxide at the substrate for a high quality epitaxial film to be grown. If the surface oxygen content is high enough, it will detrimentally affect the growth of any epitaxial Si on the SiGe layer.

A typical method for removing residual surface oxygen from Si substrates for high-quality Si and SiGe epitaxy, is annealing the substrate at high temperature (>1000° C.) in a hydrogen atmosphere (hydrogen pre-bake). Alternatively, hydrogen pre-bake can be combined with an ex-situ hydrofluoric acid (HF) etch of the substrate prior to loading it into the epitaxy chamber. The HF etch will passivate the surface with Si—H bonds, which slows down the native oxide growth. Only a moderate hydrogen pre-bake (≦900C, 30 sec-120 sec) is required to remove the remaining oxide following the HF etch.

However, in the development of strained Si materials, it is often required to deposit Si on partially or fully relaxed SiGe. The relaxed SiGe has a larger lattice constant than Si. As a result, Si grown on top of this relaxed SiGe is under tensile strain. CMOS transistors built on strained Si have shown improved performance, due to higher electron and hole mobilities. Strained Si is a promising material for next generation high performance CMOS circuits.

FIG. 1 illustrates a layer of SiGe 10 with an overlying oxide/oxygen region 12 that forms naturally in an ambient atmosphere containing oxygen (O₂ or H₂O). The circles within region 12 schematically illustrate oxygen atoms within the substrate 10. Region 12 is not actually a separate layer of the substrate 10, but instead is the upper surface region of the substrate 10 that contains the oxygen atoms. If there is a sufficient amount of oxygen within the region 12, this will detrimentally affect the growth of any epitaxial silicon on the SiGe layer 10. Therefore, as shown in FIG. 2, an etching and hydrogen pre-bake process can be utilized to remove the oxygen/oxide from region 12. However, by completely removing the oxygen/oxide region 12 with hydrogen pre-bake, it is observed that the surface 20 of the SiGe layer 10 becomes rough, as shown in FIG. 2.

More specifically, a hydrogen pre-bake (such as an 800° C., 2 minute pre-bake) following an ex-situ HF etch is an efficient method to completely remove the remaining oxygen from region 12. However, while such a pre-bake removes all of the oxygen from region 12, it also makes the surface 20 very rough, as shown in FIG. 2. Further study indicated that the roughening of the SiGe surface is related to the surface oxygen removal. The measure of trace amounts of oxygen (and other elements) on a surface is typically given as the integral of the atomic concentration over the depth distribution and thus has the units of area density (atoms/cm²) and one atomic layer is on the order of 1×10¹⁵ atoms/cm². When a small amount of oxygen remains (>5×10¹²/cm²), the surface stays smooth. Once this residual oxygen is removed, the surface quickly becomes rough at the pre-bake temperature. This is most likely because the surface diffusivity of Si and Ge is reduced due to the presence of the residual oxygen. The surface roughening is caused, in part, by surface Si and Ge diffusion. Rough semiconductor surfaces can interfere with the quality of thermally-grown gate oxide layers in FET processing as well as degrade the performance of CMOS device due to increased carrier scattering at the rough interface. High oxygen at the Si/SiGe interface can create epitaxial growth defects in the Si layer and thus degrade the performance of the CMOS device. Therefore, there is a need to minimize the residual oxygen concentration on the surface of SiGe without significantly increasing the roughness of the surface.

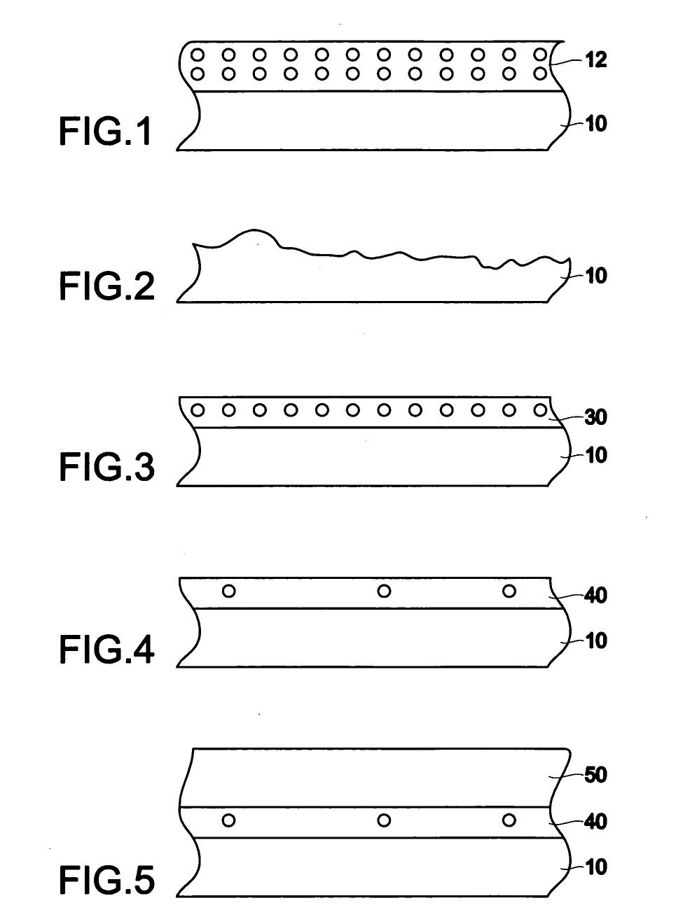

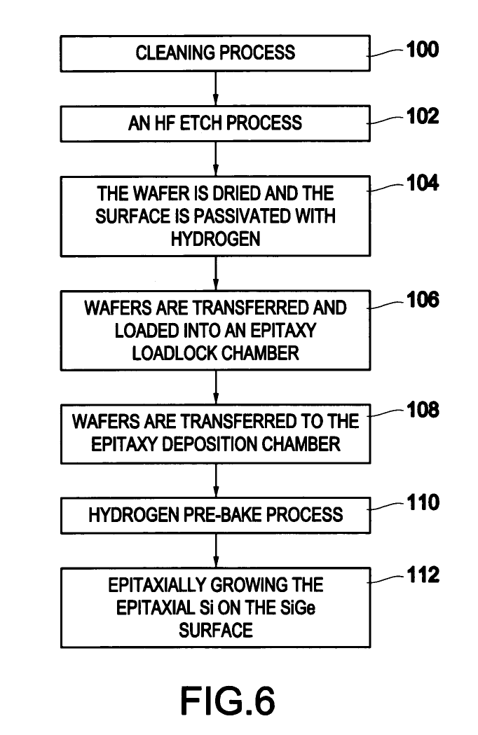

In a separate patent application which is cross-referenced above, a method of leaving a small amount of oxygen during hydrogen prebake to prevent surface roughening is claimed by the same inventors. However, it is also desirable to remove all the oxygen on the SiGe surface. The invention performs the processing shown below to remove all oxygen without substantially roughening the SiGe surface. A typical HF etch will remove most of the native oxide, but still leaves a small amount of oxygen 30 at the SiGe surface as shown in FIG. 3, due to reoxidation during wafer drying and exposure to the ambient during wafer transferring from etch chamber to epitaxy chamber. Note that there are substantially less oxygen atoms within region 30 in FIG. 3 than there were originally in region 12 in FIG. 1. Additional treatment is required in order to further reduce the residual surface oxygen level. Although hydrogen pre-baking is an efficient method for removing the remaining oxygen, the inventors have found that when all the oxygen at the surface is removed, the SiGe surface quickly becomes very rough in a hydrogen ambient (e.g., FIG. 2). This roughening can be measured, for example, by atomic force microscopy (AFM). The invention described here utilizes a hydrogen pre-bake in the presence of chlorine after the HF etch to remove the remaining oxygen without making the surface rough (region 50 shown in FIG. 5). FIG. 4 illustrates the pre-bake process that is performed without the presence of chlorine. In such a process, the amount of oxygen is substantially reduced to produce region 40. However, the small amount of oxygen (>5×10¹²/cm²) remains in region 40 to prevent surface roughening. To avoid having to leave a small amount of oxygen in the region 40, the invention introduces chlorine containing gas into the pre-bake process to remove all oxygen from the surface as shown by region 50 in FIG. 5. Thus, region 40 in FIG. 4 contains even less oxygen concentration than the amount of oxygen in region 30 shown in FIG. 3 and illustrates the result of performing a hydrogen pre-bake without the use of chlorine containing gas. Region 50 illustrates the removal of all oxygen without surface roughening through the use of the chlorine containing environment pre-bake process. FIG. 6 illustrates the epitaxial layer 60 grown over the region 50 that has had substantially all the oxygen removed.

As shown in FIG. 7, an HF etch process 102 is used first to remove most of the oxide at the surface. A diluted HF solution is typically used for this etching process, such as typically 10:1-500:1 H₂O:HF solution, preferably 50:1-200:1 H₂O:HF solution. Cleaning processes 100 that remove particles, metals, organic contaminations can be performed before HF etch. After the HF etch, the wafer is dried 104 without rinse (HF last), or it can be rinsed with diluted HCl solution (HCl last), or DI water before drying. HF last or HCl last process is preferred as it minimizes the reoxidation of the SiGe surface. The SiGe surface after this HF etch is passivated with hydrogen which slows down the reoxidation during the time the wafer is exposed to an oxygen-containing environment, such as when it is transferred from the HF etch chamber to the epitaxy chamber. This HF etch process removes most of the oxide at the surface, however, small amount of oxygen remains at the surface, typically with a dose of 1×10¹³-1×10¹⁵/cm² oxygen. The amount of remaining oxygen depends on the etching process and Ge content at the SiGe surface. The higher the Ge content, the more the remaining oxygen. An oxygen dose of 5×10¹³-2×10¹⁴/cm² is typically observed on SiGe surface with 15-25% Ge content, while higher oxygen doses are possible with a non-optimized HF etch process.

The SiGe wafers are then transferred and loaded into an epitaxy loadlock chamber 106 within a time window. The time window can be as long as a few hours before the SiGe surface starts to be reoxidized significantly in the ambient. A time window of less than 1 hour is preferred to guarantee minimum reoxidation. The loadlock chamber of the epitaxy tool is purged with high-purity inert gas, such as high-purity nitrogen. A loadlock chamber that is capable of having the ambient evacuated (pumped loadlock) is preferred as it can quickly reduce the oxygen and moisture content in the loadlock to below the parts-per-million (ppm) level during a purge cycle. The wafers can then be transferred to the epitaxy deposition chamber 108.

An oxygen amount of >1×10¹⁴/cm² is too much oxygen to properly grow the epitaxial silicon. At this level of surface oxygen, regions exist at the surface where silicon atoms are displaced from their epitaxial positions by atomic-scale clusters of oxygen atoms. This local atomic displacement can create an error in the subsequent atomic ordering as the layer is grown thicker. A defect that is characteristic of this phenomenon is the so-called stacking fault tetrahedron or hillock defect.

A hydrogen pre-bake process 110 within the epitaxy deposition chamber or a separate baking chamber in the same tool is then used to remove the remaining oxygen content at the surface. While hydrogen pre-bake is effective in removing the remaining oxygen at the surface, when all the oxygen at the SiGe surface is removed during the hydrogen bake, the surface quickly becomes rough. The inventors found the surface stays smooth when there is a small amount of oxygen (e.g., sub-monolayer) remaining at the surface (>5×10¹²/cm²). For example, a 10 μm×10 μm AFM image taken before and after the hydrogen bake shows less than a 1 Å RMS roughness change for the samples with at least 5×10¹²/cm² oxygen remaining, whereas samples with no measurable remaining oxygen showed a roughness increase of more than 1 Å. The measured RMS roughness will continue to increase with increasing time or temperature in the case where there is no remaining oxygen at the surface unless the pre-bake process is performed in the presence of chlorine containing gases such as a mixture of HCl and Si₂H₂Cl₂ (DCS). This is most likely due to chlorine reducing the surface diffusivity of Si and Ge. The surface roughening is caused by surface Si and Ge diffusion.

To avoid the surface roughening, the invention performs the hydrogen pre-bake process 110 in the presence of chlorine containing gases. More specifically, by flowing a small amount of chlorine containing gas (such as a mixture of HCl and DCS) the surface is passivated by the chlorine. This chlorine passivation prevents surface roughening even if all the oxygen is removed from the surface of the SiGe. This is believed to occur because of the chlorine on the surface reduces the surface diffusivity of Si and Ge. In addition, in the subsequent epitaxial Si or SiGe growth process, the chlorine atoms on the Si or SiGe surface do not incorporate with the epitaxially grown film. Therefore, there is a very clean interface between the substrate and the epitaxially grown film. HCl etches Si and SiGe, and the etch rate depends on the temperature and the gas flow. DCS will deposit Si on the surface. The mixture of HCl and DCS can be tuned to etch or deposit film, depending upon the designer's requirements. In the case that the gas mixture deposits film, the deposition rate needs to be limited, so that the oxygen is not buried in by the deposited film. There also need to be a minimum amount of chlorine containing gas to prevent SiGe surface roughening when all the oxygen on the surface is removed. The exact amount and ratio of HCl and DCS gas flow required depend on epitaxy chamber, pre-bake temperature, and chamber pressure. A thumb of rule is to start with an HCl and DCS mixture that has zero deposition rate, and make sure the flow is high enough that the surface doesn't become rough when all surface oxygen is removed. If there is a need to etch SiGe film in-situ before growing epitaxial film, one can increase HCl flow or reduce DCS flow to have the gas mixture etch SiGe. In general, there is no need to grow Si during the pre-bake, although pre-bake with a small growth rate (such as less than 0.4 Å/sec at 825° C.) is observed to still be able to remove all surface oxygen.

The hydrogen pre-bake process 110 is carried out in an ultra-clean chamber, in an ultra-pure hydrogen environment, with less than 1 ppm of oxygen and moisture, preferably with less than 10 ppb of oxygen and moisture, with the environment containing a small amount of HCl and DCS, with partial pressure of HCL and DCS in the range of 1 mTorr-1 Torr, preferably 20 mTorr-200 mTorr, in the temperature range of 700° C.-900° C., preferably 750° C.-850° C. and chamber pressure range of 1 mTorr-760 Torr, preferably 5 Torr-40 Torr, for 5 sec-10 min, preferably 30 sec-2 min. The combination of HCl and DCS partial pressure, chamber pressure, temperature, and bake time is chosen so that the hydrogen pre-bake process removes the surface oxygen without roughening the surface. As mentioned above, by introducing HCl and DCS into the pre-bake process, all the oxygen can be removed without roughening the surface. Then, the process of epitaxially growing the epitaxial Si on the SiGe surface 112 is performed.

Examples of hydrogen pre-bake for 25% SiGe substrate in a chlorine containing environment performed in an Applied Materials Centura HT poly chamber are given below, with all 3 processes being able to remove the remaining oxygen and carbon on the SiGe surface.

### EXAMPLE 1

| | |
|---|---|
| H₂ | 8 slm |
| DCS | 50 sccm |
| HCl | 65 sccm |
| Pressure | 10 Torr |
| Temperature | 825° C. |
| Time | 120 sec |
| Etch rate | 0 Å/sec |

### EXAMPLE 2

| | |
|---|---|
| H₂ | 8 slm |
| DCS | 50 sccm |
| HCl | 100 sccm |
| Pressure | 10 Torr |
| Temperature | 825° C. |
| Time | 120 sec |
| Etch rate | 0.3 Å/sec |

### EXAMPLE 3

| | |
|---|---|
| H₂ | 8 slm |
| DCS | 50 sccm |
| HCl | 50 sccm |
| Pressure | 10 Torr |
| Temperature | 825° C. |
| Time | 120 sec |
| Deposition rate | 0.4 Å/sec |

Thus, the invention provides a process that combines an HF etch and chlorine containing environment hydrogen pre-bake. The HF etch removes most of oxygen at the surface. Then, this is followed with the chlorine containing environment hydrogen pre-bake, to remove the remaining oxygen. This is used successfully to keep the surface from roughening, while still removing all oxygen from the SiGe surface.

While only Si epitaxy on SiGe surface is discussed above, the invention is useful when epitaxially growing Si or SiGe on: SiGe (including SiGe on bulk substrate and SiGe on insulator), patterned strained Si (including patterned strained Si on bulk substrate and on insulator), or patterned thin SOI (such as patterned SOI with Si thickness less than 300 Å) surfaces, and avoids creating a rough surface upon which the epitaxial layer is grown.

The invention addresses a unique problem of hydrogen pre-bake of SiGe, patterned strained Si and patterned thin SOI films. This problem occurs when the surface oxygen is totally removed during hydrogen pre-bake, and the surface becomes rough.

Thus, as shown above, the invention forms an epitaxial Si or SiGe layer on a SiGe, patterned strained Si, or patterned thin SOI surface and avoids creating a rough surface upon which the epitaxial layer is grown. In order to avoid creating a rough surface, the invention first performs a HF etching process on the SiGe, patterned strained Si, or patterned thin SOI surface. The HF etching process removes most of oxide from the surface, and leaves a small amount of oxygen (typically 1×10¹³-1×10¹⁵/cm² of oxygen) at the SiGe, patterned strained Si, or patterned thin SOI surface. The invention then performs a heating process in a chlorine containing environment which heats the surface sufficiently to remove the remaining oxygen from the surface. By introducing chlorine containing gas into the heating process, the invention avoids roughening the SiGe, patterned strained Si, or patterned thin SOI surface. Then, the process of epitaxially growing the epitaxial Si or SiGe layer on the SiGe, patterned strained Si, or patterned thin SOI surface is performed.

Although a mixture of HCl and DCS is used as an example, it is also possible to use other chlorine containing gases, such as a mixture of HCl with any one or any combination of SiH₄, DCS, SiHCl₃, Si₂H₆, and GeH₄. It is also possible to use HCl only. In the above cdiscussions, the chlorine containing gases is usually mixed with a high flow of hydrogen. In the case of UHV-CVD, it is possible to use chlorine containing gases without hydrogen.

In addition to remove remaining oxygen on the surface, the pre-bake process described here also removes remaining carbon contamination on the surface. With advanced cleaning processes, remaining carbon contamination is usually very small (for example, less than 1×10¹³/cm²). The pre-bake process in a chlorine containing environment removes the remaining carbon to below SIMS detection limit.

In addition to what is described above, it is possible to use other chemical oxide removal processes instead of HF etch. Such chemical oxide removal processes remove most of the oxide on SiGe and Si surfaces and leave a small amount of oxygen at the surface. For example, one can use a gaseous mixture of HF and ammonia to remove the surface oxide. This invention is also applicable to epitaxy of other Si-containing layers on top of SiGe, patterned strained Si, or patterned thin SOI surface. Such Si-containing layers include Si, SiGe (more specifically SiₓGe₁₋ₓ), SiₓC₁₋ₓ, or SiₓGe_{y}C_{1-x-y}.

While the invention has been described in terms of preferred embodiments, those skilled in the art will recognize that the invention can be practiced with modification within the spirit and scope of the appended claims.

1. A method of forming an epitaxial silicon-containing layer on a silicon germanium surface, said method comprising:
performing an ex-situ chemical oxide removal process on said silicon germanium surface so as to remove oxygen from said silicon germanium surface, and leave a remaining amount of oxygen at said silicon germanium surface;
heating said silicon germanium surface in a chlorine containing environment to remove said remaining amount of oxygen from said silicon germanium surface; and
epitaxially growing said epitaxial silicon-containing layer on said silicon germanium surface.

2. The method in claim 1, wherein said ex-situ chemical oxide removal and heating processes increase the roughness of said silicon germanium surface by less than 1 Å RMS.

3. The method in claim 1, wherein said silicon-containing layer comprises one of Si, SiₓGe₁₋ₓ, SiₓC₁₋ₓ, and SiₓGe_{y}C_{1-x-y}.

4. The method in claim 1, wherein said ex-situ chemical oxide removal comprises a hydrofluoric acid etch.

5. The method in claim 4, where said hydrofluoric acid comprises a H₂O:HF solution with ratio of 10:1 to 500:1.

6. The method in claim 1, wherein said chlorine containing environment comprises a mixture of a larger flow of hydrogen with smaller flows of HCl and DCS.

7. The method in claim 6, where the ratio of HCl and DCS is chosen to have a zero etch rate.

8. The method in claim 7, where the ratio of HCl and DCS is chosen to have a positive etch rate.

9. The method in claim 1, wherein said chlorine containing environment comprises a mixture of a larger flow of hydrogen with smaller flow of mixture of HCl with any one or any combination of SiH₄, DCS, SiHCl₃, Si₂H₆, and GeH₄.

10. A method of forming an epitaxial silicon-containing layer on a silicon surface, said method comprising:
performing an ex-situ chemical oxide removal process on said silicon surface so as to remove oxygen from said silicon surface, and leave a remaining amount of oxygen at said silicon surface;
heating said silicon surface in a chlorine containing environment to remove said remaining amount of oxygen from said silicon surface; and
epitaxially growing said epitaxial silicon-containing layer on said silicon surface.

11. The method in claim 10, wherein said silicon surface comprises one of a patterned strained silicon surface and a patterned thin silicon-on-insulator (SOI) surface.

12. The method in claim 10, wherein said ex-situ chemical oxide removal and heating processes increase the roughness of said silicon surface by less than 1 Å RMS.

13. The method in claim 10, wherein said silicon-containing layer comprises one of Si, SiₓGe₁₋ₓ, SiₓC₁₋ₓ, and SiₓGe_{y}C_{1-x-y}.

14. The method in claim 10, wherein said ex-situ chemical oxide removal comprises a hydrofluoric acid etch.

15. The method in claim 14, where said hydrofluoric acid comprises a H₂O:HF solution with ratio of 10:1 to 500:1.

16. The method in claim 10, wherein said chlorine containing environment comprises a mixture of a larger flow of hydrogen with smaller flows of HCl and DCS.

17. The method in claim 16, where the ratio of HCl and DCS is chosen to have one of a zero etch rate and positive etch rate.

18. The method in claim 10, wherein said chlorine containing environment comprises a mixture of a larger flow of hydrogen with smaller flow of mixture of HCl with any one or any combination of SiH₄, DCS, SiHCl₃, Si₂H₆, and GeH₄.

19. A method of forming an epitaxial silicon-containing layer on a silicon surface, wherein said silicon surface comprises one of a patterned strained silicon surface and a patterned thin silicon-on-insulator (SOI) surface, said method comprising:
performing an ex-situ chemical oxide removal process on said silicon surface so as to remove oxygen from said silicon surface, and leave a remaining amount of oxygen at said silicon surface;
heating said silicon surface in a chlorine containing environment to remove said remaining amount of oxygen from said silicon surface; and
epitaxially growing said epitaxial silicon-containing layer on said silicon surface.
